(19) United States
(12) Patent Application Publication
(10) Pub. No.: US 2004/0022198 A1
(43) Pub. Date: Feb. 5, 2004

(54) Methods and apparatus for simulating random connections

(76) Inventors: Jon C. Weil, Fen Ditton (GB); David Wiggins, Belfast (GB)

Correspondence Address: William M. Lee, Jr., Lee, Mann, Smith, McWilliams,, Sweeney & Ohlson, P.O. Box 2786, Chicago, IL, 60690-2786, US

(21) Appl. No.: 10/212,608

(22) Filed: Aug. 5, 2002

(51) Int. Cl. G01R 31/08

(52) U.S. Cl. 370/252

(57) ABSTRACT

Blocking of a network element such as the switch occurs when there is remaining capacity in the switch in terms of available connections but some other problem occurs in the switch (such as lack of processing power) which causes a connection to be refused. Switches use increasingly complex algorithms to carry out switching operations, in part to optimise blocking performance, however, this makes estimation of real capacity in a switch difficult. Generating random connections for sampling purposes from the space of fully provisioned connections based on sensible estimates of bandwidth granularity, allows accurate estimates to be carried out. Appropriate shuffling and correlation techniques further enhance the real-world performance of such simulations.

### FIELD OF THE INVENTION

This invention relates to methods and apparatus for testing a network element for blocking operation.

### BACKGROUND OF THE INVENTION

Network elements in a communications network map signals on incoming interfaces to outgoing interfaces. In the following description, an element which can change its internal state to support the mapping of signals on particular incoming interfaces to particular outgoing interfaces is referred to as a “switch” and a state of the switch which maps a particular set of signals on incoming interfaces to a particular set of outgoing interfaces is referred to as a “connection”. The case of a signal on a single input interface mapping to a single output interface is one example of such a connection. In this specification, the term ‘connection’ encompasses broadcast connections, in which a signal on an input interface may be distributed to two output interfaces (bridging) or merge to a single interface to be selected (selection). These are used to support protection schemes. Bridging and selection are often used to form protected connections.

The flexibility to map a signal from an arbitrary incoming interface to any of the available outgoing interfaces, regardless of the availability of any of the other unspecified interfaces is a desirable property. This may be termed the “non-blocking” property of a switch. If a connection request is offered to a switch and all of the interfaces required by the connection are available, but the switch cannot satisfy the request because its internal resources are exhausted, the connection is “blocked”.

Often, a non-blocking architecture leads to a switch design that is too expensive to be viable in the marketplace. Clever switch control algorithms may be used in architectures to provide relatively inexpensive switch designs that are conditionally non-blocking or whose connections may be rearranged to produce non-blocking performance. The cleverness of such algorithms can however lead to unpredictable resource usage. The implementation of clever switch control algorithms presents some inherent challenges in that their feasibility may depend on complex coding. Accordingly, verifying the correctness of the algorithm implementation may best be done by brute force. Also, because the resource usage of these algorithms may be dependent on the ordering of connections applied to the switch, verifying correct behaviour in even abstract test situations can be difficult. The ability to obtain a statistically accurate picture of algorithm performance; one that models real user behaviour, is therefore desirable.

The real world requirements for a connection in a network element create considerable complexity in, and impose further requirements on, switch design.

A switch must allow for the optional, but usual cases of redundancy of connections for protection in case of internal equipment failure, and the pairing and broadcast of connections to provide protection in case of link failure. Standardized link protection schemes (such as Bidirectional Line Switched Ring [BLSR], or Unidirectional Path Switched Ring [UPSR]) often impose further complexity in the form of requirements on signalling between the interfaces.

As flexible switches have become cheaper in the marketplace, network designs which allow circuits across the network to be set up and torn down more easily have become feasible (see standards such as Asynchronous Transfer Mode [ATM], Automatic Switched Transport Network [ASTN], or Generalized Multiprotocol Label Switching [GMPLS]). A transport network designed for such dynamic use, often with distributed control, depends on an accurate picture of remaining switching capacity at each network element in order to function properly. This means that any elements that conditionally block or use sophisticated algorithms which may use resources unpredictably and have to estimate their remaining capacity may erode the behaviour of the network if their estimates are inaccurate or biased. This principle is seen to operate in today's managed networks in which the time required to set up an end-to-end connection in a current SONET/SDH network is significantly lengthened by “dropouts”. These are occasions on which a network engineer trying to establish a connection finds that capacity expected at a network element is not available. In such cases a new route must be planned. This principle is critical in any network planning a low latency signalled redial restoration.

Dynamic networks also create new design challenges. The same concerns about blocking that are found in a switch design for a network element appear again when these switches are networked and an automated signalling or management system is used to secure resources for circuits. Good estimates of remaining capacity in a dynamic distributed control network are required to facilitate appropriate upgrade and evolution strategies.

A means for efficiently producing test situations that give theoretically well founded and statistically unbiased characterizations of the performance of switching systems and networks is required. Furthermore, in order to fulfil the expectations of dynamic optical networks with distributed control, an onboard means of estimating capacity remaining in switches with unpredictable resource usage is required.

Randomly ordered sets of random connections may be used in an attempt to meet these requirements. The general prior art approach has been to add connections in an appropriate way until either the switch (or the remainder of the switch in the case of onboard estimation) is fully provisioned, or a connection is blocked. Statistics may be used to assess switch designs or estimate capacity by modelling the application of connections many times in a monte carlo approach.

Previous approaches to generate such random sets of test connections suffer from both practical and theoretical difficulties. Two approaches are typically used. In the first, signal identifiers are randomly sampled independently in each coordinate for an input and then and for an output interface. When both an available input and output have been found, a connection is recorded. In the second, a list of available input and output signals is kept and consulted by randomly choosing an offset into the list. The first approach suffers from “spurious” blocking. Inputs or outputs that occur from the random process may represent signals already selected and must be discarded and another attempt made. Discarding the random numbers can have adverse theoretical impacts (random numbers are a carefully managed resource because of correlations that can occur when random number generators cycle) and practical impacts (tests run for a long time as more and more resources are allocated). When implemented efficiently, the second approach may incur significant accounting overhead. Neither approach provides a consistent sampling model. Both create dependencies on the realization of the sample. This is because the distribution that is sampled from changes over the course of the trial. This is not the proper underlying model. Both approaches also create difficulties with categories of signals and the broadcast case.

### SUMMARY OF THE INVENTION

It is desirable that an algorithm that produces sets of random connections be efficient and quick to execute in practice. The connections must be able to model arbitrary bandwidth resolution and schemes that support equipment and network protection. This implies that broadcast connections as well as any labelling or categorization required by internal algorithms should ideally be supported. It is desirable that the algorithm produce sets of connections randomly, but that this randomness model the correlation induced by real operation of switch.

In accordance with a first aspect of the invention therefore, there is provided a method of generating random connections for testing a network element for blocking operation comprising generating an ordered list of input identifiers for the input ports of the network element, generating an ordered list of output identifiers for the output ports of the network element, randomly assigning bandwidth resolutions according to desired proportions to each identifier in the lists, separating the lists into bandwidth resolution categories as well as any other required categories, shuffling the identifiers within each category, forming a connection list of notional connections by traversing each of the lists in a predetermined order and recording pairs of respective input and output identifiers each pair representing a notional connection, and shuffling the connection list.

In this way, the connection lists of notional connections which may be applied to a switch or a switch algorithm in order to test its blocking capability, is sampled from the space of a fully provisioned switch. The sample space created by generating the ordered list of input and output identifiers is produced using common sense assumptions. For example, the sample space may be generated based on certain assumptions about the resolution of the connections (i.e. choices of optical connection type such as STS-48 and STS-12). Different resolutions may have Implications for the number of ports which are actually available on the switch before any blocking or switching algorithm factors are taken into account. Thus the population of different resolutions or other category of connections is made based on the typical expected usage of the switch. Thus in essence, the solution is to fully (or appropriately) provision a switch according to some assumptions of randomness for example, the distribution of resolutions (such as STS-48 and STS-12) which appropriately represents real use of the switch, and then to randomise the interconnections by shuffling i.e. by swapping entries in an ordered list of connections in a predetermined way. This technique is powerful when used to solve sophisticated problems involving the types of connections and correlations of connections and also the types of provisioning behaviour expected in switches in the real world. The solution has several benefits. It is practical. It does not cause spurious blocking. It runs faster than the common approaches. It has theoretical efficiencies. Primarily this is true because it stems from the correct model. It is amenable to abstract analysis in ways that the common approach is not because the common approaches have adhoc elements. It also does not waste random numbers. This has both practical and theoretical impacts in that it runs faster and makes the best use of the random number generator. Additionally, it does not incur the accounting complexities of the second prior art approach described above.

The algorithm above may be used to create software or hardware to test switches and switch control software or firmware. It may be used in software to test network designs. It may be used in software to forecast required capacity for upgrade of networks/switches. It may be used to estimate remaining capacity on switches or in networks in a live network situation, in order to provide accurate available resource statistics to routing and pathfinding components.

In accordance with a second aspect of the invention, there is provided a method of generating random connections for testing a network element for blocking operation comprising generating an ordered list of identifiers for the ports of the network element, randomly assigning bandwidth resolutions according to desired proportions to each identifier in the list, separating the lists into bandwidth resolution categories as well as any other required categories, generating an input list and an output list by dividing the list into an equal number of input and output identifiers in each category, shuffling the identifiers within each category, forming a connection list of notional connections by traversing the input list and the output list in a predetermined order and recording pairs of respective input and output identifiers each pair representing a notional connection, forming the inverse connections to produce the counterpart required for bidirectionality and add these to the connection list, and shuffling the connection list.

This allows for the creation of bi-directional notional connections in which each connection in one direction has an inverse connection in the opposite direction at the same bandwidth resolution or selected from the same category of connection according to other criteria and bandwidth resolution.

As a further enhancement, this method aspect may further comprise separating each notional connection into an input and an output identifier, grouping respective input and output identifiers into pairs and for each pair, generating associated fixed and movable virtual cards each containing the pair of identifiers from which the virtual cards were generated, and assigning a notional broadcast connection from an identifier in a first fixed virtual card to a pair of identifiers in a second movable virtual card generated from a different pair of input and output identifiers.

In this way, broadcast connections may be generated in the notional connection list which as discussed allows blocking performance to be determined for switches used in protection circuits.

As a yet further enhancement, the method may also comprise assigning an inverse notional broadcast connection from an identifier in a second fixed virtual card associated with second movable virtual card to a pair of identifiers in a first movable virtual card associated with the firs fixed virtual card. This allows for bi-directional protected connections to be tested for blocking performance.

In a third aspect there is provided a method of estimating capacity in a network element comprising generating an ordered list of input identifiers for the input ports of the network element, generating an ordered list of output identifiers for the output ports of the network element, randomly assigning bandwidth resolutions according to desired proportions to each identifier in the lists, separating the lists into bandwidth resolution categories as well as any other required categories, shuffling the identifiers within each category, forming a connection list of notional connections by traversing each of the lists in a predetermined order and recording pairs of respective input and output identifiers each pair representing a notional connection, shuffling the connection list, and applying the connections to the network element until blocking occurs or the connection list is exhausted and reporting the number of connections successfully made as an estimate of capacity in the network element.

In a fourth aspect the invention provides a method of estimating bidirectional capacity in a network element comprising generating an ordered list of identifiers for the ports of the network element, randomly assigning bandwidth resolutions according to desired proportions to each identifier in the list, separating the lists into bandwidth resolution categories as well as any other required categories, generating an input list and an output list by dividing the list into an equal number of input and output identifiers in each category, shuffling the identifiers within each category, forming a connection list of notional connections by traversing the input list and the output list in a predetermined order and recording pairs of respective input and output identifiers each pair representing a notional connection, forming the inverse connections to produce the counterpart required for bidirectionality and add these to the connection list, shuffling the connection list, and applying the connections to the network element until blocking occurs or the connection list is exhausted and reporting the number of connections successfully made as an estimate of capacity in the network element.

In a fifth aspect of the invention there is provided a network element including a processor operable to estimate capacity in the network element and arranged to generate an ordered list of input identifiers for the input ports of the network element, generate an ordered list of output identifiers for the output ports of the network element, randomly assign bandwidth resolutions according to desired proportions to each identifier in the lists, separate the lists into bandwidth resolution categories as well as any other required categories, shuffle the identifiers within each category, form a connection list of notional connections by traversing each of the lists in a predetermined order and recording pairs of respective input and output identifiers each pair representing a notional connection, shuffle the connection list, and apply the connections to the network element until blocking occurs or the connection list is exhausted and reporting the number of connections successfully made as an estimate of capacity in the network element.

In a further aspect of the invention there is provided a network element including a processor operable to estimate bidirectional capacity in the network element and arranged to generate an ordered list of identifiers for the ports of the network element randomly assign bandwidth resolutions according to desired proportions to each identifier in the list, separate the lists into bandwidth resolution categories as well as any other required categories, generate an input list and an output list by dividing the list into an equal number of input and output identifiers in each category, shuffle the identifiers within each category, form a connection list of notional connections by traversing the input list and the output list in a predetermined order and recording pairs of respective input and output identifiers each pair representing a notional connection, form the inverse connections to produce the counterpart required for bidirectionality and add these to the connection list, shuffle the connection list, and apply the connections to the network element until blocking occurs or the connection list is exhausted and reporting the number of connections successfully made as an estimate of capacity in the network element.

In another aspect the invention provides a computer program on computer readable medium which when executed on a processor associated with a switching algorithm of a network element, is operable to cause the algorithm to respond to notional connections generated by generating an ordered list of input identifiers for the input ports of the network element, generating an ordered list of output identifiers for the output ports of the network element, randomly assigning bandwidth resolutions according to desired proportions to each identifier in the lists, separating the lists into bandwidth resolution categories as well as any other required categories, shuffling the identifiers within each category, forming a connection list of notional connections by traversing each of the lists in a predetermined order and recording pairs of respective input and output identifiers each pair representing a notional connection, and shuffling the connection list.

In yet a further aspect of the invention there is provided a computer program on computer readable medium which when executed on a processor associated with a switching algorithm of a network element, is operable to cause the algorithm to respond to notional connections generated by generating an ordered list of identifiers for the ports of the network element, randomly assigning bandwidth resolutions according to desired proportions to each identifier in the list, separating the lists into bandwidth resolution categories as well as any other required categories, generating an input list and an output list by dividing the list into an equal number of input and output identifiers in each category, shuffling the identifiers within each category, forming a connection list of notional connections by traversing the input list and the output list in a predetermined order and recording pairs of respective input and output identifiers each pair representing a notional connection, forming the inverse connections to produce the counterpart required for bidirectionality and add these to the connection list, and shuffling the connection list.

Other aspects and features of the present invention will become apparent to those ordinarily skilled in the arts upon review of the following description of specific embodiments of the invention in conjunction with the accompany figures.

### BRIEF DESCRIPTION OF THE DRAWINGS

FIG. 1 is a schematic diagram of the formation of notional connection lists for unidirectional connections;

FIG. 2 is a schematic diagram showing the creation of notional connection lists for bi-directional connections;

FIG. 3 is a schematic diagram showing the creation of notional connection lists for bi-directional broadcast connections; and

FIG. 4 is a schematic block diagram of a network control element including a capacity estimator in accordance with the present invention and controlling a network element.

### DETAILED DISCLOSURE OF THE PREFERRED EMBODIMENTS

The invention may be encoded into software or designed into a hardware circuit to test SONET/SDH transport network element switch cores and switch control components. This functionality may reside in test equipment outside a network element or on board a network element. When on board, the functionality may be used to report estimates of remaining capacity to a signalling switch controller, network element manager or management system by performing the algorithm on available resources and reporting the result.

The functionality may also be deployed on a control element which contains a copy of the switch control algorithm (see p26, of the slidepack referenced above) and data about existing and available resources which may be used to provide a capacity estimate and subsequently provision the switch. On-line estimates may be computed as a diagnostic, after connections are applied, upon command, triggered subject to a thresholded measurable, or periodically.

By focusing attention on an appropriate theoretical model, a practical technique offers itself. By way of example, take the case of assessing the blocking performance in a simple nonblocking switch. To provide a proper sample for a monte carlo simulation, the applicant chooses to sample from the space of fully provisioned switches. That is to say that the population from which it is wished to uniformly sample is the population of fully provisioned switches such that each switch represents one of all possible combinations of inputs and outputs. Consider for this case that we are not attempting to model realistic user behaviour, but considering only the possibility of blocking in the widest case (hence the population space of all possible combinations, sampled uniformly).

The chief benefit of the approach is that it is flexible. It gives modellers control over the proportion of connection bandwidth resolutions, categories and broadcast and allows them to more closely approximate real world situations. It gives control over correlations among connections and their order of application that more accurately model user behaviour.

In our model, it is useful in the general case to allow hierarchical addressing of the elements in order to represent bandwidth resolution and interface groupings. This approach is particularly useful for capturing time division multiplexing within a switch. Consider a hierarchical address to be a list of identifiers. Dependencies between interfaces may be created by schemes used to provide redundant connections for protection. These groupings can be can be captured by appending an identifier to create a super class. Similarly, some algorithms may require that signals be categorized or prioritised. This may modelled by appending an identifier as well.

In summary, the exemplarary algorithms are as follows:

Let the interfaces with their available signals be represented by an ordered list of identifiers for the input signals and one for the output signals.

1. Randomly assign bandwidth resolutions according to desired proportions to build the lists.

2. Separate the lists into bandwidth resolution categories as well as any other required categories.

3. Shuffle within these categories.

4. Form connections by walking through each of the lists in order and record in a new list.

5. Shuffle the new list.

6. Correlations may be induced into the shuffles by shuffling blocks of elements, maintaining the order within these blocks. This can be accomplished by partitioning the list before shuffling. Correlation may be controlled by modelling the size of these blocks stochastically or by allowing them to have sizes determined by a function. A second approach is to use a random offsetting procedure to determine which block to shuffle as well as a random process to determine its size.

When dealing with bi-directional connections with assumptions of symmetry, the algorithm is modified. Start with a single list of available signals with an even number of signals supported

1. Randomly assign bandwidth resolutions according to desired proportions to build the list

2. Separate the lists into bandwidth resolution categories as well as any other required categories.

3. Split each of the category lists into an input list and an output list, each list of equal size.

4 Shuffle within these categories.

5. Form connections by walking through each of the lists in order and record in a new list.

6. Form the inverse connections to produce the counterpart required for bidirectionality. And add these to the list.

7. Shuffle the new list.

8. Correlations may be induced into the shuffles by shuffling blocks of elements, maintaining the order within these blocks. This can be accomplished by partitioning the list before shuffling. Correlation may be controlled by modelling the size of these blocks stochastically or by allowing them to have sizes determined by a function. A second approach is to use a random offsetting procedure to determine which block to shuffle as well as a random process to determine its size.

As a further extension, rules may be used guide the manner in which inputs are matched to outputs by guiding the selection of category lists when making connections. When combined with broadcast this supports sophisticated switch control rearrangement algorithms.

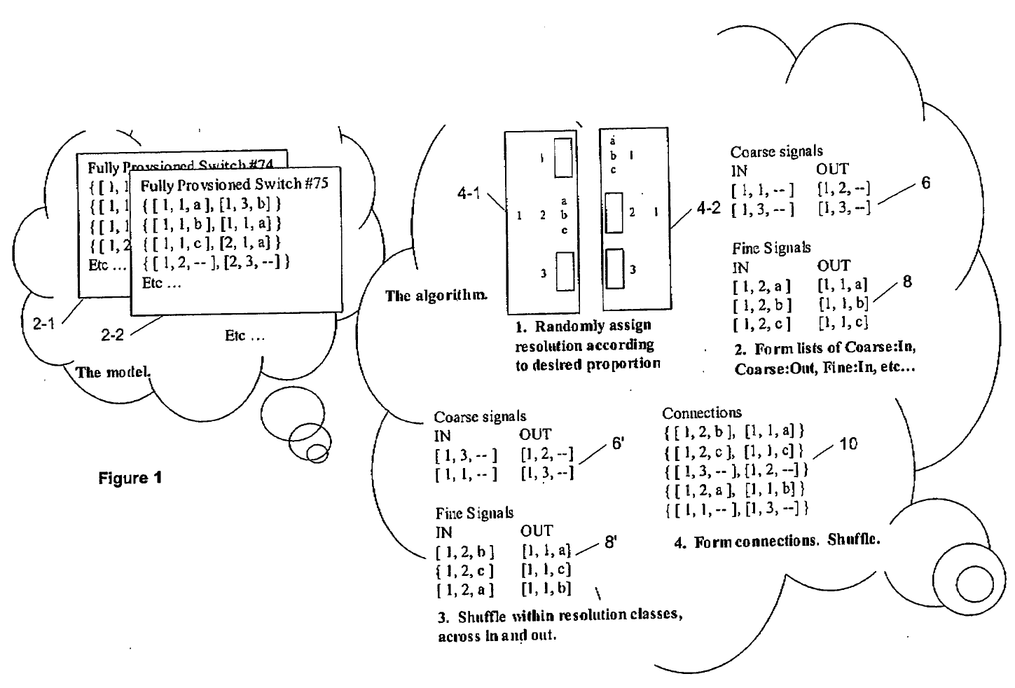

With reference now to FIG. 1, the creation of a notional connection list which may be used in the ways described above, for unidirectional connections is shown. A plurality of switches 2-1 and 2-2 are represented as lists of fully provisioned input and output connections. The notation used in the figure (for example 1,1,a) may mean for example shelf 1, card 1 and port a of card 1 on shelf 1.

Similarly, the notation 1,1,b is port b of the same card (i.e. card 1 on shelf 1). This is the hierarchical notation discussed above. With additional identifiers, the connection may be formed into different categories and superclasses as discussed above.

In the cloud on the right side of FIG. 1, the algorithm is shown schematically. Boxes 4-1 and 4-2 are diagramatic representations of the lists shown for a single fully provisioned switch 2-1 or 2-2. The leftmost box 4-1 denotes input connections and the rightmost box 4-2 denotes output connections. In this example, only two bandwidth resolutions are used namely “fine” and “coarse”. In the boxes 4-1 and 4-2, coarse signals such as those connected to cards 1 and 3 of shelf 1 in the input box 4-1 do not allow connections directly to ports on those cards since all ports will be tied to a single connection. The fine input connection on card 2 allows access to the three ports a, b and c since these may be independently connected to different lower bandwidth, finer resolution, connections.

Firstly, the signals are sorted into categories; in this example into coarse signals 6 and fine signals 8. The connections are then shuffled (i.e. the association between inputs and outputs is randomised) within the coarse and fine categories to generate the lists 6′ and 8′. The final list is then made by walking through the categories in order to pull out in and out connection pairs making notional complete uni-directional connections. Once this list is prepared, the list itself is re-ordered to form the final notional connection list 10.

This connection list then contains a set of random connections to apply to a switch or switch algorithm to test blocking performance and yet which has a chosen distribution of fine and coarse signals which typically is chosen to represent real world usage of the switch.

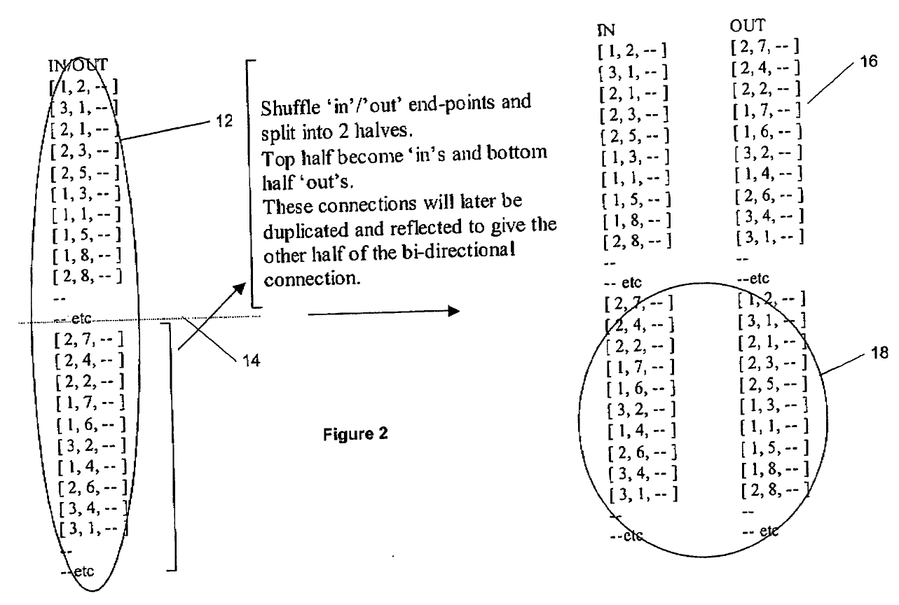

With reference to FIG. 2, a similar example to FIG. 1 is shown but in this case the connections are made as notional bi-directional connections. In this example, instead of generating separate lists for inputs and outputs, a single list of all possible connections (whether inputs or outputs) on the switch is made. This “fully provisioned” list is made in the same way as in FIG. 1 in the sense that it is made taking into account any desired bandwidth granularity. Furthermore, it is made including any additional category identifiers which may be desired. As before, the list is then separated into its different categories. At this point, the category list 12 is split in half as denoted by the dotted line 14 in FIG. 2. These lists are then split into an input list and an output list each of equal size. The list then generated is denoted 16 in FIG. 2. The connections are then recorded in the final list by walking through the in and out entries in order. Inverse connections 18 are then generated as mirror images of the connection 16 to produce bi-directional connections. This is carried out for each category to generate a final list which is then shuffled in the same way as list 10 of FIG. 1.

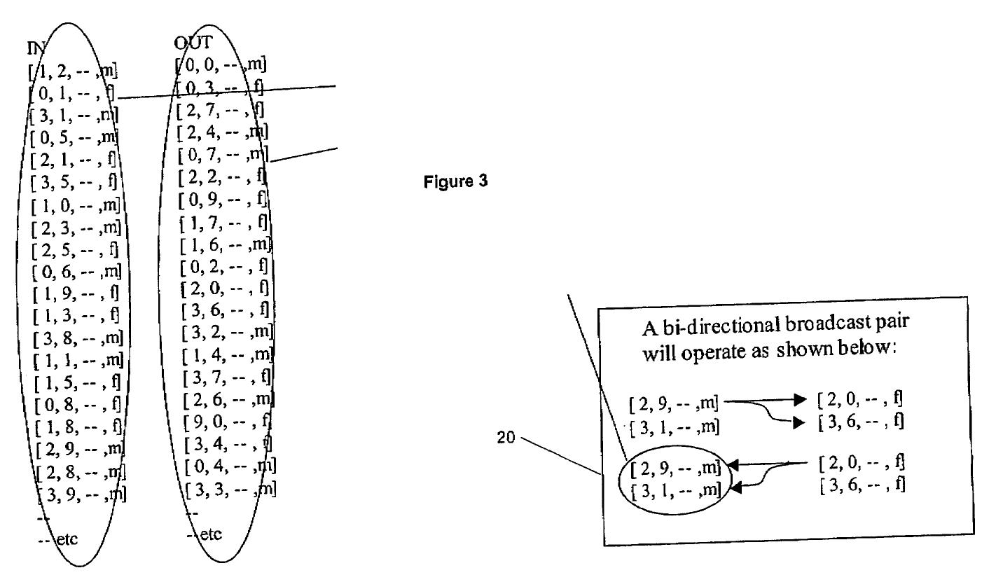

As a further enhancement, the bi-directional connections may be broadcast connections as shown in FIG. 3.

Having created bi-directional connections in the manner described in connection with FIG. 2, pairs of be-directional connections of the same category may then be grouped into two “virtual cards”; a so-called “fixed” card and a “movable” card. Each pair of virtual cards maps to a pair of physical bi-directional connections as prepared in the way shown in FIG. 2.

Thus with two virtual cards, there are four physical connection possibilities, namely two possibilities in each direction. This is enough for protection for a bi-directional connection which is to be protected in both directions.

The general principle is shown in the box marked 20 in FIG. 3. Having carried out the steps shown in FIG. 2 up to the point of producing shuffled connections within a category, only one half of each bi-directional connection is used and then formed into the virtual cards as described above. Connections are then assigned so that a movable connection (for example 2, 9, -, m in box 20), has a choice of two possible protection paths through the switch namely 2, 0, - f or 3, 6, - f. In reverse, the connection into 2, 0, -, f is protected by having a choice of 2, 9, -, m or 3, 1, -, m as protected paths.

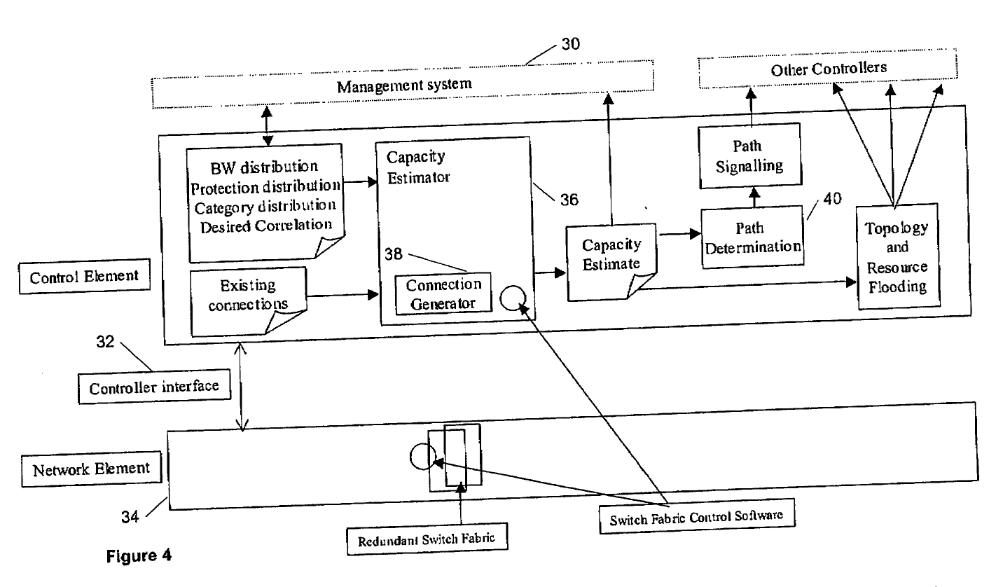

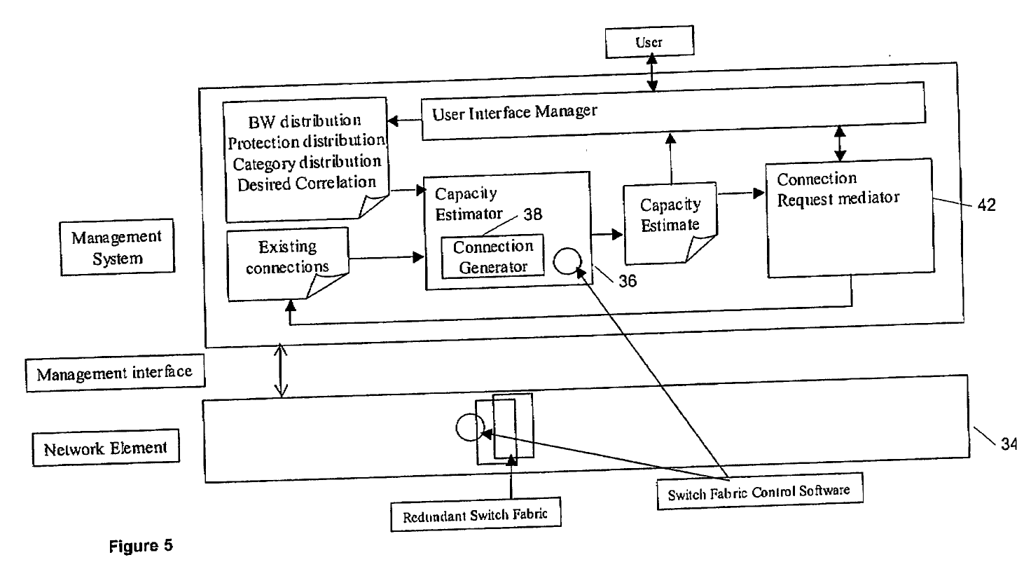

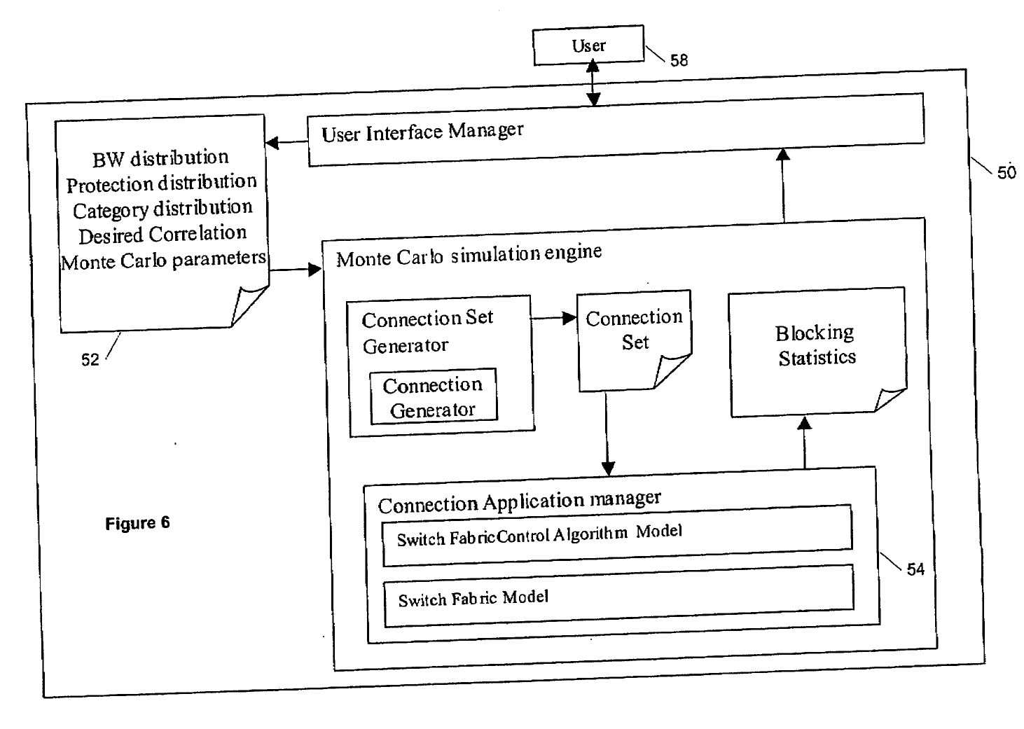

With reference to FIG. 4, a control element 30 includes the ability to estimate the remaining capacity in a network element 32. A capacity estimator includes a connection generator 34 which carries out the steps immediately above. The capacity estimator is informed of existing connections 36 and an expected mix of connections 38 to allow appropriate categories to be simulated. Knowledge of the existing connections is used to remove these from the sample space since these are already provisioned. The control element may then apply the generated notional connections to a copy of an algorithm used within the network element 32 for carrying out switching. The algorithm may then be tested to determine at what point blocking occurs and then a capacity estimate 40 may be produced and fed back to the management layer of the network.

1. A method of generating random connections for testing a network element for blocking operation comprising:
(a) generating an ordered list of input identifiers for the input ports of the network element,
(b) generating an ordered list of output identifiers for the output ports of the network element,
(c) randomly assigning bandwidth resolutions according to desired proportions to each identifier in the lists,
(d) separating the lists into bandwidth resolution categories as well as any other required categories,
(e) shuffling the identifiers within each category,
(f) forming a connection list of notional connections by traversing each of the lists in a predetermined order and recording pairs of respective input and output identifiers each pair representing a notional connection, and
(g) shuffling the connection list.

2. A method according to claim 1, further comprising partitioning the ordered lists of input and output identifiers into blocks containing respective subsets of the identifiers and shuffling the blocks without disturbing the order of the identifiers within the blocks whereby predetermined correlations may be induced into the shuffles.

3. A method according to claim 2, wherein the block sizes are determined by stochastic modelling or according to a predetermined mathematical function, whereby the degree of correlation may be controlled.

4. A method according to claim 1, further comprising partitioning the ordered lists of input and output identifiers into blocks containing respective subsets of the identifiers and shuffling the blocks and the identifiers within at least some of the blocks without disturbing the order of the identifiers within all the blocks whereby predetermined correlations may be induced into the shuffles.

5. A method according to claim 4, wherein the block sizes are determined by stochastic modelling or according to a predetermined mathematical function, whereby the degree of correlation may be controlled.

6. A method of generating random connections for testing a network element for blocking operation comprising:
(a) generating an ordered list of identifiers for the ports of the network element,
(b) randomly assigning bandwidth resolutions according to desired proportions to each identifier in the list,
(c) separating the lists into bandwidth resolution categories as well as any other required categories,
(d) generating an input list and an output list by dividing the list into an equal number of input and output identifiers in each category,
(e) shuffling the identifiers within each category,
(f) forming a connection list of notional connections by traversing the input list and the output list in a predetermined order and recording pairs of respective input and output identifiers each pair representing a notional connection,
(g) forming the inverse connections to produce the counterpart required or bidirectionality and add these to the connection list, and
(h) shuffling the connection list.

7. A method according to claim 6, further comprising partitioning the ordered lists of input and output identifiers into blocks containing respective subsets of the identifiers and shuffling the blocks without disturbing the order of the identifiers within the blocks whereby predetermined correlations may be induced into the shuffles.

8. A method according to claim 7, wherein the block sizes are determined by stochastic modelling or according to a predetermined mathematical function, whereby the degree of correlation may be controlled.

9. A method according to claim 6, further comprising partitioning the ordered lists of input and output identifiers into blocks containing respective subsets of the identifiers and shuffling the blocks and the identifiers within at least some of the blocks without disturbing the order of the identifiers within all the blocks whereby predetermined correlations may be induced into the shuffles.

10. A method according to claim 9, wherein the block sizes are determined by stochastic modelling or according to a predetermined mathematical function, whereby the degree of correlation may be controlled.

11. A method according to claim 6 further comprising separating each notional connection into an input and an output identifier, grouping respective input and output identifiers into pairs and for each pair, generating associated fixed and movable virtual cards each containing the pair of identifiers from which the virtual cards were generated, and assigning a notional broadcast connection from an identifier in a first fixed virtual card to a pair of identifiers in a second movable virtual card generated from a different pair of input and output identifiers.

12. A method according to claim 11 comprising assigning an inverse notional broadcast connection from an identifier in a second fixed virtual card associated with second movable virtual card to a pair of identifiers in a first movable virtual card associated with the firs fixed virtual card.

13. A method of estimating capacity in a network element comprising:
(a) generating an ordered list of input identifiers for the input ports of the network element,
(b) generating an ordered list of output identifiers for the output ports of the network element,
(c) randomly assigning bandwidth resolutions according to desired proportions to each identifier in the lists,
(d) separating the lists into bandwidth resolution categories as well as any other required categories,
(e) shuffling the identifiers within each category,
(f) forming a connection list of notional connections by traversing each of the lists in a predetermined order and recording pairs of respective input and output identifiers each pair representing a notional connection,
(g) shuffling the connection list, and
(h) applying the connections to the network element until blocking occurs or the connection list is exhausted and reporting the number of connections successfully made as an estimate of capacity in the network element.

14. A method of estimating bidirectional capacity in a network element comprising:
(a) generating an ordered list of identifiers for the ports of the network element,
(b) randomly assigning bandwidth resolutions according to desired proportions to each identifier in the list,
(c) separating the lists into bandwidth resolution categories as well as any other required categories,
(d) generating an input list and an output list by dividing the list into an equal number of input and output identifiers in each category,
(e) shuffling the identifiers within each category,
(f) forming a connection list of notional connections by traversing the input list and the output list in a predetermined order and recording pairs of respective input and output identifiers each pair representing a notional connection,
(g) forming the inverse connections to produce the counterpart required for bidirectionality and add these to the connection list,
(h) shuffling the connection list, and
(i) applying the connections to the network element until blocking occurs or the connection list is exhausted and reporting the number of connections successfully made as an estimate of capacity in the network element.

15. A network element including a processor operable to estimate capacity in the network element and arranged to:
(a) generate an ordered list of input identifiers for the input ports of the network element,
(b) generate an ordered list of output identifiers for the output ports of the network element,
(c) randomly assign bandwidth resolutions according to desired proportions to each identifier in the lists,
(d) separate the lists into bandwidth resolution categories as well as any other required categories,
(e) shuffle the identifiers within each category,
(f) form a connection list of notional connections by traversing each of the lists in a predetermined order and recording pairs of respective input and output identifiers each pair representing a notional connection,
(g) shuffle the connection list, and
(h) apply the connections to the network element until blocking occurs or the connection list is exhausted and reporting the number of connections successfully made as an estimate of capacity in the network element.

16. A network element including a processor operable to estimate bidirectional capacity in the network element and arranged to:
(a) generate an ordered list of identifiers for the ports of the network element,
(b) randomly assign bandwidth resolutions according to desired proportions to each identifier in the list,
(c) separate the lists into bandwidth resolution categories as well as any other required categories,
(d) generate an input list and an output list by dividing the list into an equal number of input and output identifiers in each category,
(e) shuffle the identifiers within each category,
(f) form a connection list of notional connections by traversing the input list and the output list in a predetermined order and recording pairs of respective input and output identifiers each pair representing a notional connection,
(g) form the inverse connections to produce the counterpart required for bidirectionality and add these to the connection list,
(h) shuffle the connection list, and
(i) apply the connections to the network element until blocking occurs or the connection list is exhausted and reporting the number of connections successfully made as an estimate of capacity in the network element.

17. A computer program on computer readable medium which when executed on a processor associated with a switching algorithm of a network element, is operable to cause the algorithm to respond to notional connections generated by:
(a) generating an ordered list of input identifiers for the input ports of the network element,
(b) generating an ordered list of output identifiers for the output ports of the network element,
(c) randomly assigning bandwidth resolutions according to desired proportions to each identifier in the lists,
(d) separating the lists into bandwidth resolution categories as well as any other required categories,
(e) shuffling the identifiers within each category,
(f) forming a connection list of notional connections by traversing each of the lists in a predetermined order and recording pairs of respective input and output identifiers each pair representing a notional connection, and
(g) shuffling the connection list.

18. A computer program on computer readable medium which when executed on a processor associated with a switching algorithm of a network element, is operable to cause the algorithm to respond to notional connections generated by:
(a) generating an ordered list of identifiers for the ports of the network element,
(b) randomly assigning bandwidth resolutions according to desired proportions to each identifier in the list,
(c) separating the lists into bandwidth resolution categories as well as any other required categories,
(d) generating an input list and an output list by dividing the list into an equal number of input and output identifiers in each category,
(e) shuffling the identifiers within each category,
(f) forming a connection list of notional connections by traversing the input list and the output list in a predetermined order and recording pairs of respective input and output identifiers each pair representing a notional connection,
(g) forming the inverse connections to produce the counterpart required for bidirectionality and add these to the connection list, and
(h) shuffling the connection list.
